(19) United States
(12) Patent Application Publication
(10) Pub. No.: US 2026/0068574 A1
(43) Pub. Date: Mar. 5, 2026

(54) OPTIMIZED DICING STREET/KERF FOR CHIPLET APPLICATION

(71) Applicant: INTERNATIONAL BUSINESS MACHINES CORPORATION, ARMONK, NY (US)

(72) Inventors: Qianwen Chen, Chappaqua, NY (US); Fabian Benthaus, Mohegan Lake, NY (US); Cheng-Wei Cheng, White Plains, NY (US); Roy R. Yu, Poughkeepsie, NY (US); Katsuyuki Sakuma, Fishkill, NY (US)

(21) Appl. No.: 18/820,163

(22) Filed: Aug. 29, 2024

(51) Int. Cl. H01L 21/78; B23K 26/38; B23K 26/53; B23K 101/40; H01L 21/304; H01L 23/00; H01L 23/58

(52) U.S. Cl. CPC H01L 21/78; B23K 26/38; B23K 26/53; B23K 2101/40

(57) ABSTRACT

A semiconductor device includes a substrate having a plurality of dies. A dielectric layer is arranged on the substrate including a plurality of Back End of Line (BEOL) interconnects, and a plurality of dummy metal structures. A dicing street is arranged between the dies. A high-refraction low-absorptance layer is arranged on the substrate below the dummy metal structures, and the high-refraction low-absorptance layer covers at least a partial area of the dicing street between the dice.

### BACKGROUND

### Technical Field

The present disclosure generally relates to 3D packaging applications for semiconductor structures, and more specifically, to a method of wafer dicing for semiconductor structures.

### Description of the Related Art

In recent years, there has been a trend to reduce the height of 3D semiconductor structures. Such 3D semiconductor structures were previously constructed by forming dies on the wafer, and blade-cutting the dice into individual dies, followed by bonding (e.g., hybrid bonding) the dies together in a desired structure. Blade-cutting of the dice requires a wide dicing street, and there is a tendency to have a reduced yield because of cracks caused by the blade-cutting. As the size of the semiconductors continues to be reduced, stealth dicing (using an IR laser instead of a blade) is now increasing in popularity. An IR laser is selected having a particular wavelength and power suitable to cut (or make perforations in) the Si substrate on which the dice are formed. However, the interaction of the laser beam with dummy metal structures (used as crack stops and for moisture blocking) causes damage to the metal and causes dielectric layer delamination on the dice. The metal damage and dielectric delamination from the laser beam make hybrid bonding of the dice difficult to achieve.

### SUMMARY

In one embodiment, a semiconductor device includes a substrate having a plurality of dies. A dielectric layer is arranged on the substrate including a plurality of Back End of Line (BEOL) interconnects, and a plurality of dummy metal structures. A dicing street is arranged between the dice. A high-refraction low-absorptance layer is arranged on the substrate below the dummy metal structures, and the high-refraction low-absorptance layer covers at least a partial area of the dicing street between the dice. A more efficient dicing of the wafer with less debris and improved hybrid bonding results.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conventional wafer being diced with a stealth laser beam.

FIG. 1B shows a top view of a wafer with damage caused by the laser beam striking dummy metal structures in a dicing street area.

FIG. 2 illustrates a semiconductor structure that reduces/eliminates dicing damage from a stealth laser, consistent with an illustrative embodiment.

FIG. 3 illustrates a semiconductor structure that reduces/eliminates dicing damage from a stealth laser, consistent with another illustrative embodiment.

FIG. 4A illustrates a lower-level metal interconnect of a fabrication process flow, consistent with an illustrative embodiment.

FIG. 4B illustrates a dielectric etching on a refraction region of a fabrication process flow, consistent with an illustrative embodiment.

FIG. 4C illustrates a deposited refraction-enhanced layer and a high-refraction layer of a fabrication process flow, consistent with an illustrative embodiment.

FIG. 4D illustrates the building of an upper-level interconnect and dummy metal structures of a fabrication process flow, consistent with an illustrative embodiment.

FIG. 5 shows a semiconductor structure after stealth dicing has been performed, consistent with an illustrative embodiment.

FIG. 6 is a flowchart illustrating the operations to construct a semiconductor, consistent with an illustrative embodiment.

### DETAILED DESCRIPTION

### Benefits and Counterparting

In an embodiment, which may be combined with the preceding embodiment, the high-refraction low-absorptance layer covers an entire area of the dicing street between the dice. Covering the entire area of the dicing street may reduce the chance of the laser beam damaging the dummy metal structures during dicing.

In an embodiment, which may be combined with one or more preceding embodiments, the width of the high refraction/low absorptance layer ranges from about 10 um to 100 um. This range is particularly effective with an IR laser used for wafer dicing.

In an embodiment, which may be combined with one or more preceding embodiments, at least two high refraction/low absorptance layers are arranged side-by-side with a distance therebetween sized for passage of a laser beam. The two side-by-side layers permit the laser to pass and not have errant energy strike the dummy metal structures and cause damage during dicing.

In an embodiment, which may be combined with one or more preceding embodiments, the distance between the at least two high refraction/low absorptance layers ranges from about 40 um to 60 um. This range is suitable for laser beams used for stealth dicing which have a width in this range.

In an embodiment, which may be combined with one or more preceding embodiments, the high refraction/low absorptance layer is a metal layer. A metal layer in the refraction region prevents damage from errant laser refraction.

In an embodiment, which may be combined with one or more preceding embodiments, the high-refraction low-absorptance layer is at least one of Al, Ta, or Au. These are some types of materials that are not affected by the heat generated during dicing and have high-refraction low-absorptance of the incident laser beam during dicing.

In an embodiment, which may be combined with one or more preceding embodiments, the high-refraction low-absorptance layer reflects >95% and absorbs <2% of incident laser energy of a laser wavelength >1 um. The reflection and absorptance percentages may provide for wafer dicing without laser damage to improve hybrid bonding, and to reduce and/or eliminate cleaning of debris.

In an embodiment, which may be combined with one or more preceding embodiments, the high-refraction low-absorptance layer includes multiple sub-layers including a high refraction sub-layer arranged on one or more refraction-enhanced sub-layers. Multiple refraction-enhanced sublayers with different indices of refraction, and the high refraction sub-layer, maximizes the refraction, and minimizes the absorptance of the laser beam used for dicing.

In an embodiment, which may be combined with one or more preceding embodiments, the high refraction sub-layer is a metal sub-layer, and the refraction-enhanced sub-layers are a stack of alternately arranged higher-index dielectrics and lower-index dielectrics. Multiple refraction-enhanced sublayers with different indices of refraction, and the high refraction sub-layer, maximizes the refraction, and minimizes the absorptance of the laser beam used for dicing.

In an embodiment, which may be combined with one or more preceding embodiments, the high refraction sub-layer is Al. The refraction-enhanced sub-layers include the higher-index dielectrics including. The lower-index dielectrics include SiN and SiO₂. The aforementioned specific materials are particularly efficient to enhance the laser dicing operation of the semiconductor.

In an embodiment, which may be combined with one or more preceding embodiments, a thickness of the high refraction sub-layer is greater than a thickness of the higher dielectric sub-layer or the low-dielectric sublayer. There is an improvement in the refraction amount and a reduction in the amount of absorptance using the relative thicknesses as disclosed.

In one embodiment, a method of constructing a semiconductor device includes providing a substrate having a plurality of dies. A dielectric layer is arranged on the substrate and includes a plurality of Back End of Line (BEOL) interconnects. A high-refraction low-absorptance layer is deposited on the substrate that covers at least a partial area of a dicing street between the dice. A more efficient dicing of the wafer with less debris and improved hybrid bonding results.

In an embodiment, which may be combined with the preceding embodiment, a plurality of dummy metal structures is arranged in the dielectric layer adjacent to the BEOL interconnects. Depositing the high-refraction low-absorptance layer on the substrate includes first depositing one or more refraction-enhanced sub-layers on the substrate, and depositing a high refraction sub-layer on the one or more refraction-enhanced sub-layers. The combination of the high-refraction sub-layer and the refraction-enhanced sublayers maximize the refraction, and minimize the absorptance of the laser beam used for dicing.

In an embodiment, which may be combined with one or more preceding embodiments, the refraction-enhanced sub-layers deposited on the substrate form a stack of alternately arranged higher-index dielectrics and lower-index dielectrics. The high refraction sub-layer is a metal sub-layer. The combination of a metal sub-layer arranged on a stack of dielectric layers with difference indices of refraction provides for increased refraction and reduced absorptance of laser energy.

In an embodiment, which may be combined with one or more preceding embodiments, the refraction-enhanced sub-layers deposited on the substrate include the higher-index dielectric constructed of SiN, and the lower-index dielectric is constructed of SiO₂. The high refraction sub-layer is constructed of Al. The aforementioned specific materials are particularly efficient to enhance the laser dicing operation of the semiconductor.

In an embodiment, which may be combined with one or more preceding embodiments, a deposited thickness of the high refraction sub-layer is greater than a deposited thickness of the higher dielectric sub-layer or the low-dielectric sublayer. There is an improvement in the refraction amount and a reduction in the amount of absorptance using the relative thicknesses as disclosed.

In an embodiment, which may be combined with one or more preceding embodiments, arranging the high-refraction low-absorptance layers includes depositing at least two high-refraction low-absorptance layers arranged side-by-side with a distance therebetween sized for passage of a laser beam. The two high-refraction low-absorptance layers arranged side-by-side permit the laser to pass and not have errant energy strike the dummy metal structures and cause damage during dicing.

In an embodiment, which may be combined with one or more preceding embodiments, the depositing of the at least two high-refraction low-absorptance layers side-by-side includes the distance therebetween sized between 40 um to 60 um for passage of the laser beam. This range is suitable for laser beams used for stealth dicing that have a width in this range.

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. As used herein, the term “street width” is the area between the dies. As used herein, the term “kerf” refers to a width of material removed during cutting the wafer into dies. After the wafer is processed, the wafer is cut to form separate chips, and the area where the cutting is performed and the material removed is the kerf.

Wafer dicing has been conventionally performed using a blade (e.g., blade dicing). As dies have become thinner, any sidewall chipping has increased the possibility of cracking the die. Stealth dicing, which uses laser irradiation to perform the cutting, is increasing in popularity.

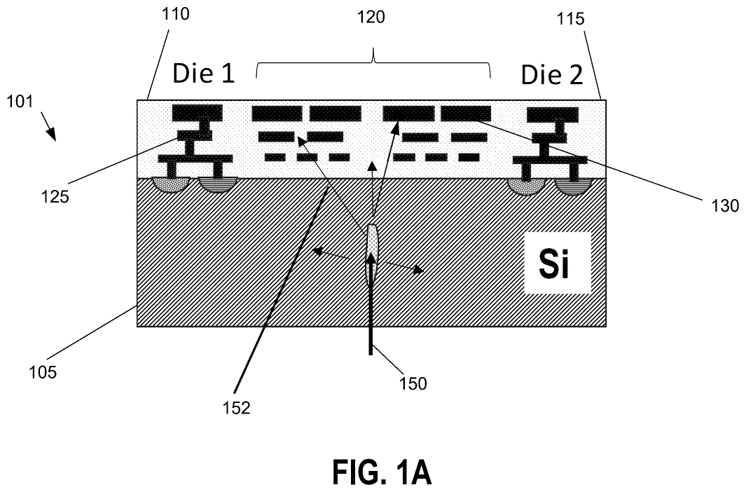

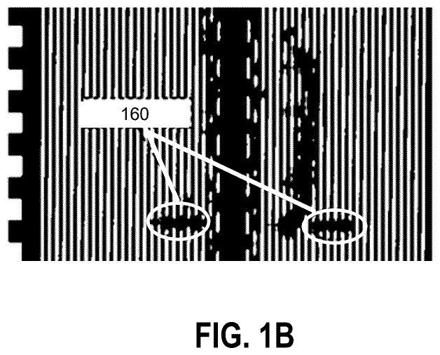

FIG. 1A shows a dicing laser beam 150 used to separate two dies 110, 115 arranged on a substrate 105. It can be seen that the die 110 and the die 115 have interconnected circuitry (e.g. Back End of Line (BEOL) interconnects 125, whereas a dummy metal structure 130 is arranged on the substrate in the dicing street area 120 to serve as a crack stop and/or moisture block. The dummy metal structure 130 is often constructed of a Damascene Cu and a liner. The liner used may be constructed of a layer of Ti or TiN. All of the aforementioned metals have a relatively high IR absorptance, and easily absorb a scattering laser energy that occurs during cutting. Thus, the scattering laser energy 152 from the laser beam 150 may damage the dummy metal structure 130 and also cause surface dielectric layer delamination. A quantity of debris from the damage to the dummy metal structure 130 may contaminate the structure and interfere with hybrid bonding of the semiconductor structure 101 with another structure.

FIG. 1B shows a top view of a wafer with damage caused by the laser beam striking dummy metal structures in a dicing street area. The circled areas 160 show laser damage to the metal.

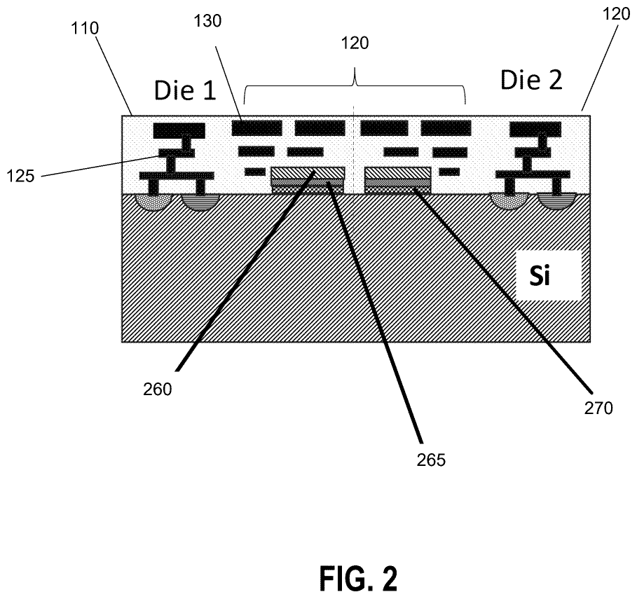

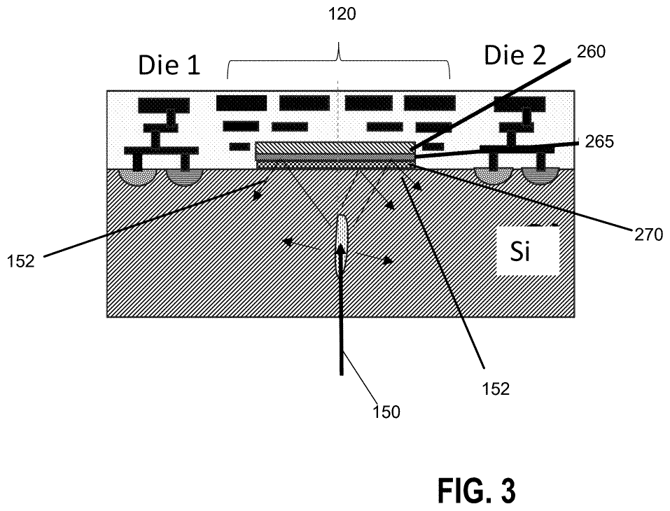

According to illustrative embodiments, such as shown in FIG. 2 or FIG. 3, the semiconductor structure includes additional layers arranged in the refraction region along the dicing street layer. These additional layers may refract as much as 95% or more of the laser beam 150 and reduce absorption to less than 2% of the laser. The cutting of the semiconductor structure 101 into separate dies can be performed without damage caused by the laser beam heating and braking of the dummy metal structures 130 during the cutting process. The result is a cleaner, more accurate cutting of the semiconductor structure.

### Example Embodiment

FIG. 2 shows a semiconductor structure that reduces/eliminates dicing damage from a stealth laser consistent with an illustrative embodiment. The semiconductor structure is similar to FIG. 1A in terms of a substrate (typically but not limited to Si) and a dielectric region with BEOL interconnects 125. Dummy metal structures 130 provide crackstop and moisture prevention during the fabrication process.

With continued reference to FIG. 2, a high-refraction low-absorptance layer includes a highly refractive layer 260, which may be a metal layer such as Al, Ta, Au, etc. There can be difficulty in depositing the highly refractive layer 260 directly on the substrate. Optionally, a refraction-enhanced stack may be used with two different dielectric materials, and the highly refractive layer 260 is arranged on top of the stack of refraction-enhanced layers 265, 270. The refraction-enhanced layers 265, 270 may have alternately higher and lower refractive indexes. For example, SiN and SiO₂ may be used. In one non-limiting example provided for illustrative purposes, the refraction-enhanced layers 265, 270 are formed of a layer of SiO₂ 120 nm thick, and SiN 60 nm thick, and the highly refractive layer 260 is Al 60 nm thick. By adding the aforementioned layers on the substrate in the dicing street area 120, there can be greater than 95% reflection and less than 2% absorption of incident laser energy (e.g., a wavelength of 1 um). This structure can prevent laser damage from occurring on the top crack stop layer during the dicing of the wafer.

FIG. 3 shows a semiconductor structure that reduces/eliminates dicing damage from a stealth laser consistent with another illustrative embodiment. FIG. 3 shows the high-refraction low-absorptance layer is a contiguous structure, whereas in FIG. 2, there is a spacing between two structures. FIG. 3 shows an incident laser beam 150 being used to dice the wafer (the laser beam passing through the substrate from the bottom of the wafer, and when it strikes the structure of highly refractive layer 260, and refraction-enhanced layers 265, 270, there is a significant amount of refracted laser energy 152 (shown by the arrows) away from the dummy metal structures in the dicing street area 120. It is to be understood that the refraction-enhanced layers 265, 270 could be a single material, but the higher and lower dielectric materials such as SiN and SiO₂ provide an enhanced result. In addition, the highly refractive layer 260 is typically a metal layer such as Al, Ta, or Au. However, metals other than Al, Ta, or Au, or even a non-metal material that can refractive the laser and withstand the temperature during laser dicing, may be used.

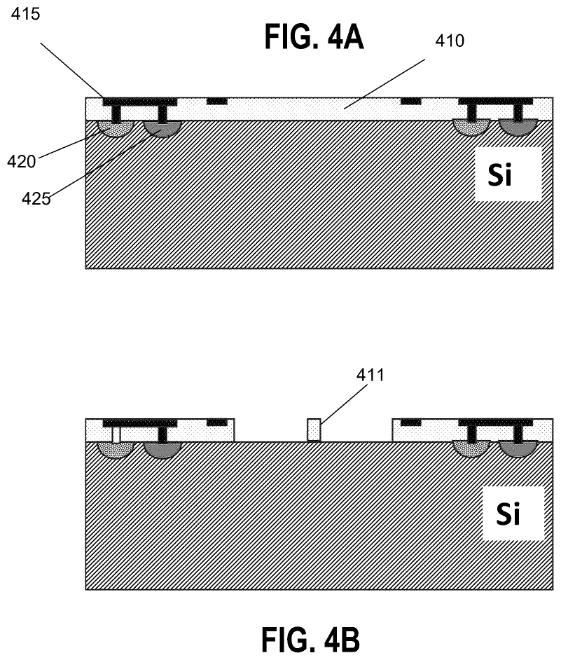

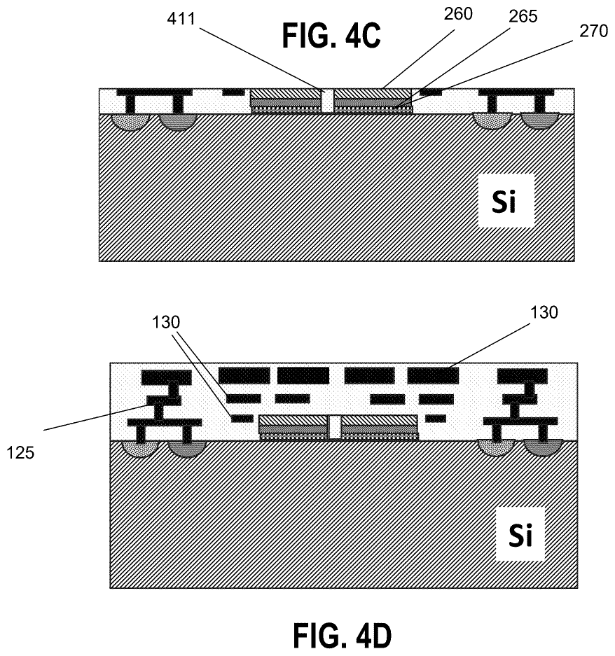

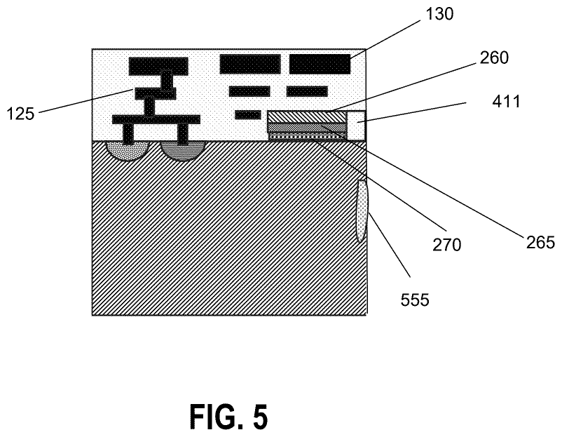

FIG. 4A shows a lower-level metal interconnect of a fabrication process flow, consistent with an illustrative embodiment. In FIG. 4A the dielectric 410 is deposited on the substrate, and interconnect 415 and materials 420, 425, which may be polysilicon (p-doped or n-doped), are arranged on the substrate.

FIG. 4B shows a dielectric etching on a refraction region of a fabrication process flow, consistent with an illustrative embodiment It is shown that a piece of dielectric 411 remains in the center of the surface of the substrate, and there are remaining areas of the dielectric 411 where the BEOL interconnects (e.g. 125 in FIG. 2) will be formed on the lower-level metal interconnects 415. The piece of dielectric 411 left in the refraction region is used when a structure, as shown in FIG. 2, is being built. If the high-refraction low-absorptance layer is a contiguous structure, as shown in FIG. 3, (also described herein above), then the dielectric etching would not leave the piece of dielectric 411 shown in FIG. 4B. The dielectric 411 may be sized to permit a laser (e.g. 50 um to 100 um) to pass through. In addition, the dielectric 411 may be removed after the high-refraction low-absorptance layers are added, as shown in FIG. 2.

FIG. 4C shows a deposited refraction-enhanced layer and a high-refraction layer of a fabrication process flow, consistent with an illustrative embodiment. In this example, the refraction-enhanced layers 265, 270 are first deposited on the substrate. Then the highly refractive layer 260 is deposited on the stack of the refraction-enhanced layers 265, 270.

FIG. 4D shows the building of an upper-level interconnect and dummy metal structures of a fabrication process flow, consistent with an illustrative embodiment. The BEOL interconnects 125 and the dummy metal structures 130 are shown. The dummy metal structures serve as a crack stop and provide moisture protection during the fabrication process.

FIG. 5 shows a semiconductor structure after a stealth laser dicing has been performed, consistent with an illustrative embodiment. There is shown a stealth laser mark 555 from where the wafer was diced. In addition, the high-refraction low-absorptance layer (e.g., typically constructed of layers 260, 265, and 270) is shown. The dielectric 411 remaining from the etching is also shown.

### Example Process

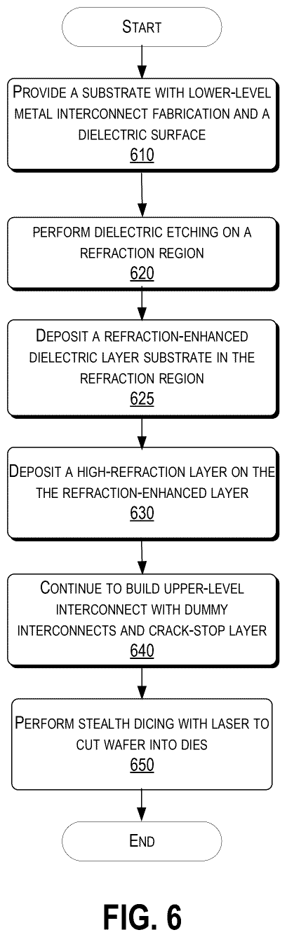

With the foregoing overview of the example architecture, it may be helpful now to consider a high-level discussion of an example process. To that end, FIG. 6 provides a flowchart illustrating the operations to construct a semiconductor consistent with an illustrative embodiment. FIG. 6 may be better understood by viewing FIGS. 4A through 4D for an example of the process.

FIG. 6 is shown as a collection of blocks, in a logical order, which represents a sequence of operations that can be implemented in a combination thereof.

A substrate (such as Si) is provided with a lower-level metal interconnect (See FIG. 4A 415) and a dielectric arranged on the substrate surface (dielectric 410 in FIG. 4A) at operation 610.

Dielectric etching above the substrate surface is then performed on a refraction region (see FIG. 4B) at operation 620. The dielectric may be completely removed from the refraction region or a piece of dielectric 411 may remain depending on how it is desired to deposit the high-refraction low-absorptance layer.

A refraction-enhanced layer or layer stack is deposited on the substrate at operation 625. The refraction-enhanced layer may be a single material, or alternately arranged materials having different refractive indices (such as SiN and SiO₂). Layers 265 and 270 shown in FIG. 4C is one such example of alternately stacked layers.

A high-refraction layer is deposited on the refraction-enhanced layers at operation 630. This layer may be a metal layer 260 (see FIG. 4C) such as Al, Ta, Au, etc. FIG. 4C shows the highly refractive layer 260 is arranged on the stack of refraction-enhanced layers 265, and 270.

After the high-refraction low-absorptance layers are arranged in the refraction region (operations 625 and 630), upper-level interconnects are built along with dummy interconnects and a crack stop layer (operation 640). FIG. 4D shows the BEOL interconnects 125, and dummy metal structures 130. Laser dicing is then performed to cut the lasers into dies at operation 650. The laser may be an IR laser. The foregoing process provides much cleaner cuts than blade dicing or laser dicing previously performed, as the additional structure in the refraction region prevents damage to the dummy metal structures 130 that adversely affects the hybrid bonding of the cut dies.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

The flowchart, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate having a plurality of dies;
a dielectric layer arranged on the substrate including a plurality of Back End of Line (BEOL) interconnects, and a plurality of dummy metal structures;
a dicing street arranged between the dies; and
a high-refraction low-absorptance layer arranged on the substrate below the dummy metal structures, wherein the high-refraction low-absorptance layer covers at least a partial area of the dicing street between the dies.

2. The semiconductor device according to claim 1, wherein the high-refraction low-absorptance layer covers an entire area of the dicing street between the dies.

3. The semiconductor device according to claim 2, wherein a width of the high-refraction low-absorptance layer ranges from about 10 um to 100 um.

4. The semiconductor device according to claim 1, wherein at least two high-refraction low-absorptance layers are arranged side-by-side with a distance between sized for passage of a laser beam.

5. The semiconductor device according to claim 4, wherein the distance between the at least two high-refraction low-absorptance layers ranges from about 40-60 um.

6. The semiconductor device according to claim 1, wherein the high-refraction low-absorptance layer comprises a metal layer.

7. The semiconductor device according to claim 6, wherein the high-refraction low-absorptance layer comprises at least one of Al, Ta, or Au.

8. The semiconductor device according to claim 1, wherein the high-refraction low-absorptance layer reflects >95% and absorbs <2% of incident laser energy of a laser wavelength >1 um.

9. The semiconductor device according to claim 1, wherein the high-refraction low-absorptance layer comprises multiple sub-layers including a high-refraction sub-layer arranged on one or more refraction-enhanced sub-layers.

10. The semiconductor device according to claim 9, wherein:
the high refraction sub-layer comprises a metal sub-layer; and
the refraction-enhanced sub-layers comprise a stack of alternately arranged higher-index dielectrics and lower-index dielectrics.

11. The semiconductor device according to claim 10, wherein:
the high refraction sub-layer comprises Al;
the refraction-enhanced sub-layers include the higher-index dielectrics comprising SiN; and
the lower-index dielectrics comprise SiO₂.

12. The semiconductor device according to claim 10, wherein a thickness of the high refraction sub-layer is greater than a thickness of the higher dielectric sub-layer or the lower-index dielectric sublayer.

13. A method of constructing a semiconductor device, the method comprising:
providing a substrate having a plurality of dice;
arranging a dielectric layer on the substrate including a plurality of Back End of Line (BEOL) interconnects; and
depositing a high-refraction low-absorptance layer on the substrate that covers at least a partial area of a dicing street between the dies.

14. The method according to claim 13, further comprising arranging a plurality of dummy metal structures in the dielectric layer adjacent to the BEOL interconnects.

15. The method according to claim 14,
wherein depositing the high-refraction low-absorptance layer on the substrate comprises depositing one or more refraction-enhanced sub-layers on the substrate, and
depositing a high refraction sub-layer on the one or more refraction-enhanced sub-layers.

16. The method according to claim 15, wherein:
the refraction-enhanced sub-layers deposited on the substrate comprise a stack of an alternately arranged higher-index dielectric sub-layer and lower-index dielectric sub-layer; and
the high refraction sub-layer comprises a metal sub-layer.

17. The method according to claim 16, wherein:
the refraction-enhanced sub-layers deposited on the substrate include the higher-index dielectric sublayer comprising SiN;
the lower-index dielectric sublayer comprises SiO₂; and
the high refraction sub-layer deposited on the refraction-enhanced sub-layers comprises Al.

18. The method according to claim 17, wherein a deposited thickness of the high refraction sub-layer is greater than a deposited thickness of the higher dielectric index sub-layer or the lower-index dielectric sublayer.

19. The method according to claim 15, wherein arranging the high-refraction low-absorptance layers comprises depositing at least two high-refraction low-absorptance layers arranged side-by-side with a distance therebetween sized for passage of a laser beam.

20. The method according to claim 19, wherein the depositing of the at least two high-refraction low-absorptance layers side-by-side includes providing the distance therebetween ranging from 40-60 um.
